(19) United States
(12) Patent Application Publication
(10) Pub. No.: US 2002/0195432 A1
(43) Pub. Date: Dec. 26, 2002

(54) Laser welding method and semiconductor laser module manufactured by this method

(75) Inventor: Kaoru Sekiguchi, Tokyo (JP)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: The Furukawa Electric Co., Ltd., Tokyo (JP)

(21) Appl. No.: 10/170,374

(22) Filed: Jun. 14, 2002

(30) Foreign Application Priority Data
Jun. 15, 2001 (JP) 2001-182039

(51) Int. Cl. B23K 26/22; H01S 5/00; G02B 6/36

(52) U.S. Cl. 219/121.64; 219/121.61; 372/43; 385/88

(57) ABSTRACT

When laser welding is performed by irradiating a laser beam to a objected joint portion of metals adjacently arranged, the irradiation of the laser beam is terminated after power of the laser beam is reduced in comparison with an irradiation starting time without constantly setting the power of the laser beam from the irradiation start to the irradiation termination. When the power of the laser beam is constant from the irradiation start to the irradiation termination, the metals melted by the irradiation of the laser beam are suddenly cooled and solidified by the irradiation termination of the laser beam so that various problems are caused. In contrast to this, the sudden cooling solidification of the molten metals can be restrained by terminating the irradiation of the laser beam after the power of the laser beam is reduced. Thus, it is possible to reduce the generation of a crack and an air bubble in a welding portion. Further, residual stress of the welding portion can be reduced and restrained.

### BACKGROUND OF THE INVENTION

For example, when metals adjacently are joined to each other by laser welding, a laser beam is irradiated to a objected joint portion of these adjacent metals. The metals in the objected joint portion are momentarily melted and fused by irradiation energy of this laser beam. The metals are then cooled and solidified so that these adjacent metals can be welded and joined to each other.

### SUMMARY

The present invention in one aspect provides the following laser welding method. Namely, the laser welding method comprises:

irradiating a laser beam to a objected joint portion of metals adjacently positioned, and welding and joining the metals to each other;

wherein the irradiation of the laser beam is terminated after power of the laser beam irradiated to the objected joint portion is reduced step by step or continuously.

### BRIEF DESCRIPTION OF THE DRAWINGS

Exemplary embodiments of the invention will now be described in conjunction with drawings in which:

FIG. 1A is a view for explaining one embodiment of a laser welding technique in the present invention. FIG. 1B is a view typically showing a shape example of a laser welding trace when a laser beam is irradiated to a boundary portion of metals adjacently positioned and these metals are laser-welded. FIG. 1C is a sectional view of the laser welding trace of FIG. 1B. FIG. 1D is a view typically showing a shape example of the laser welding trace when the laser beam is irradiated to the overlapping metals from their upper side and these metals are laser-welded. FIG. 1E is a typical sectional view of the laser welding trace of FIG. 1D. FIG. 1F is a view typically showing one example of the section of the laser welding trace of a columnar member (ferrule) and a rectangular parallelepiped member (fixing portion).

FIGS. 2A, 2B, 2C and 2D are views for respectively explaining other embodiments.

FIG. 3 is a model diagram showing one example of a semiconductor laser module in typical section.

FIG. 4 is a model diagram typically showing a fixing state of the ferrule to the fixing portion.

FIG. 5 is a model diagram showing one example of the ferrule.

Each of FIGS. 6A, 6B and 6C is a model diagram showing one example of the fixing portion.

FIG. 7A is a view for explaining one example of power control of the laser beam in a conventional laser welding technique. FIG. 7B is a view typically showing a shape example of the laser welding trace in the conventional laser welding technique. FIG. 7C is a typical sectional view of the laser welding trace of FIG. 7B. FIG. 7D is similarly a view typically showing another shape example of the laser welding trace in the conventional laser welding technique. FIG. 7E is a typical sectional view of the laser welding trace of FIG. 7D.

### DETAILED DESCRIPTION

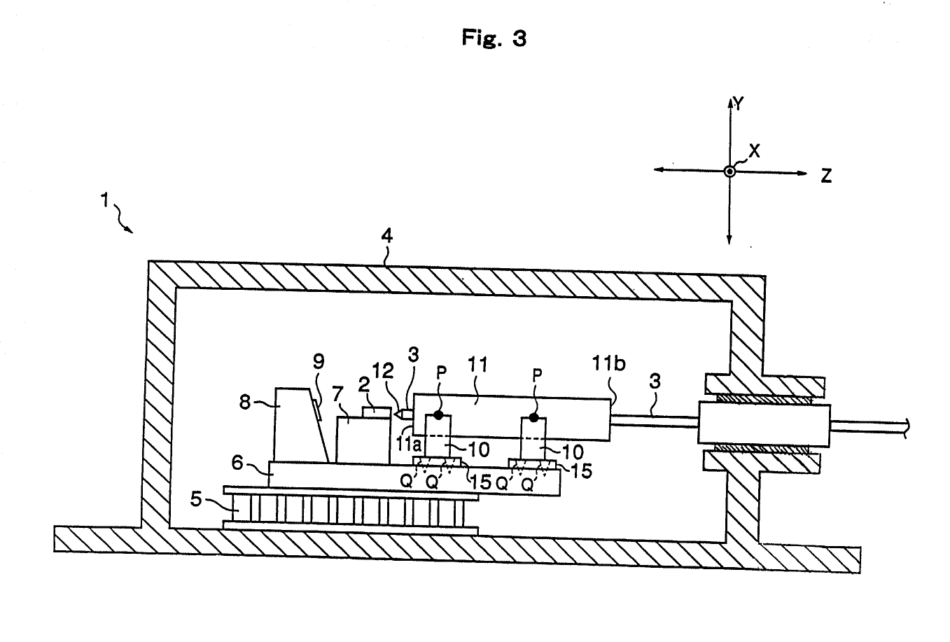

In FIG. 3, one structural example of a semiconductor laser module as one of optical parts is shown by a typical sectional view. This semiconductor laser module 1 is constructed by packaging and positioning a semiconductor laser element 2 within a package 4 in an optical coupled state to an optical fiber 3.

In this semiconductor laser module 1, a thermo module 5 is fixed to the interior of the package 4, and a metallic base 6 is fixed to an upper portion of this thermo module 5. The semiconductor laser element 2 is fixed to an upper face of the base 6 through a chip carrier 7. A photodiode 9 is fixed to this upper face of the base 6 through a support base 8. Further, an unillustrated thermistor is arranged in the vicinity of the semiconductor laser element 2.

The photodiode 9 monitors a light emitting state of the semiconductor laser element 2. The thermo module 5 controls temperature of the semiconductor laser element 2. An operation of this thermo module 5 is controlled on the basis of a detected temperature by the thermistor so as to set the temperature of the semiconductor laser element 2 to a constant temperature. A change in the temperature of the semiconductor laser element 2 is prevented by the temperature control of the thermo module 5. Thus, the changes in intensity and wavelength of a laser beam of the semiconductor laser element 2 which are originally caused by the change in the temperature of the semiconductor laser element 2, are restrained so that the intensity and the wavelength of the laser beam of the semiconductor laser element 2 are approximately set to predetermined desirable values.

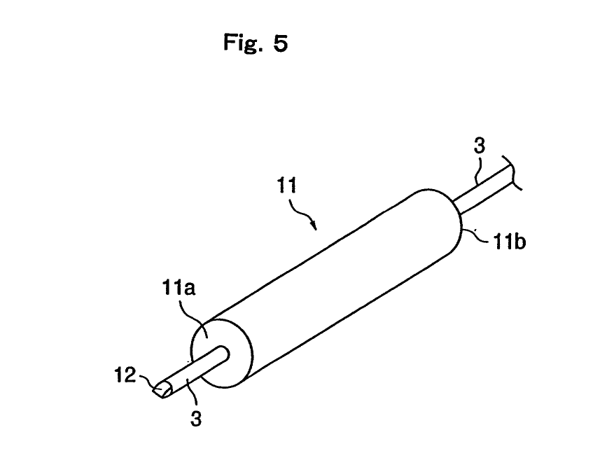

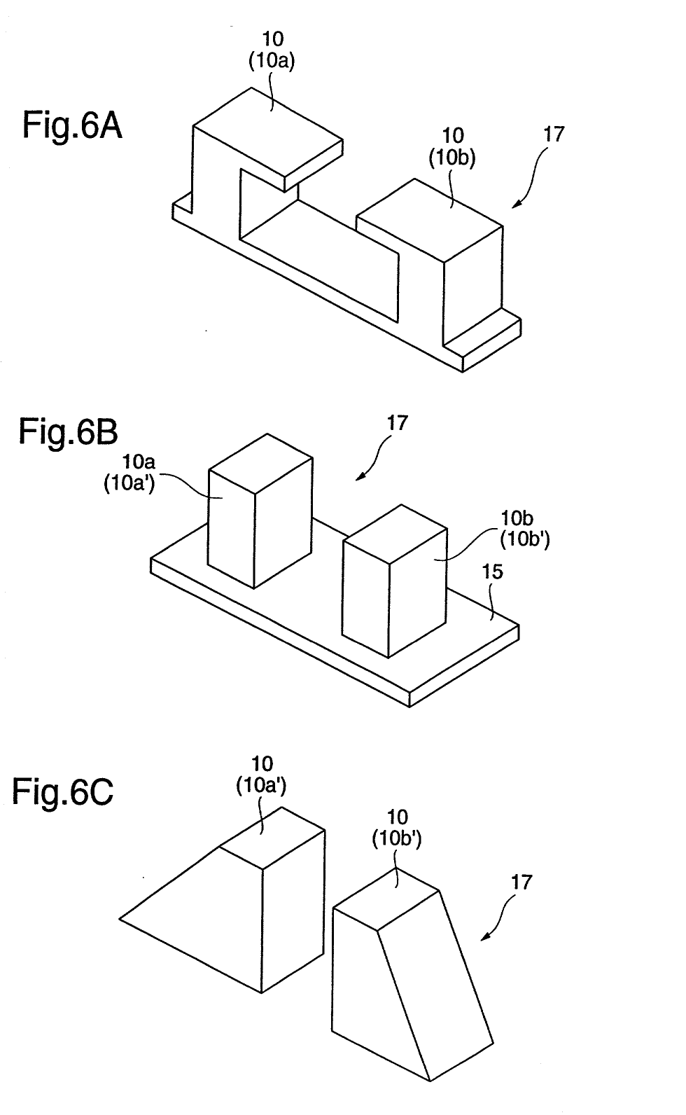

A ferrule 11 is further fixed to the base 6 through a fixing portion 10. The ferrule 11 is constructed by a metal, and is formed in a columnar shape as shown in e.g., FIG. 5. For example, an Fe—Ni—Co alloy (e.g., KOVAR (trademark)) is used as one example of the metal constituting the ferrule 11.

An unillustrated through hole is formed within the ferrule 11 such that this through hole extends from a front end face 11a to a rear end face 11b. An optical fiber 3 is inserted into this through hole, and is fixed by e.g., solder.

A tip portion of the optical fiber 3 is projected forward from the front end portion 11a of the ferrule 11, and is spaced from a light emitting portion of the semiconductor laser element 2, and receives the laser beam emitted from the semiconductor laser element 2. In this example, a lens 12 is formed in the tip portion of the optical fiber 3 so that the optical fiber 3 in this example is formed as a lensed fiber.

The optical fiber 3 pulled out of the rear end face 11b of the ferrule 11 is guided to the exterior of the package 4. The laser beam incidence to the tip portion of the optical fiber 3 from the semiconductor laser element 2 is propagated in the optical fiber 3 and is guided to a predetermined desirable supply place.

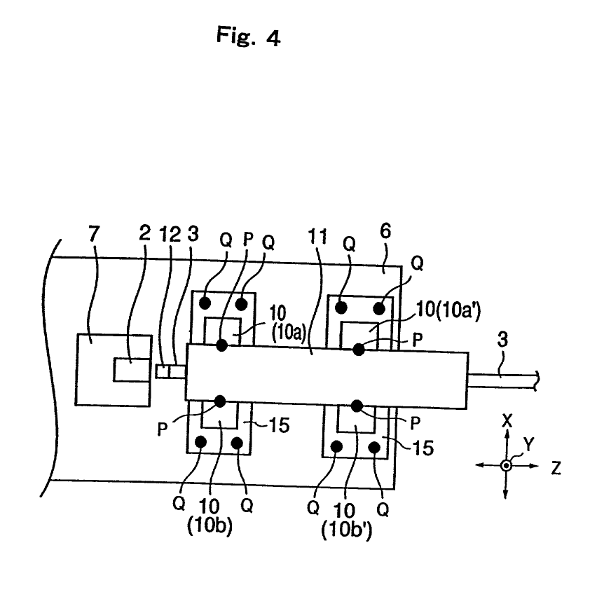

FIG. 4 shows a plane view in which a portion fixing the ferrule 11 thereto is extracted and seen from an upper side of FIG. 3. In FIG. 6A, one example of the fixing portion 10 positioned on a tip side is shown by a perspective view. FIG. 6C shows one example of the fixing portion 10 positioned on a rear side. Further, FIG. 6B shows a schematic view of the fixing portion shown in FIGS. 6A and 6B. As shown in FIG. 6A, the fixing portions 10a, 10b as a pair on the tip side constitute a part 17 for fixation of an integral type. Further, as shown in FIG. 6C, fixing portions 10a′, 10b′ as a pair on the rear side form a part 17 for fixation of a separating type (divisional type). For example, the part 17 for fixation is fixed to the base 6 by laser welding in a position Q as shown in FIGS. 3 and 4.

A side face of the ferrule 11 is nipped from both sides by a pair of fixing portions 10 (10a, 10b, 10a′, 10b′) on the tip side and the rear side. This side face of the ferrule 11 is joined to the fixing portions 10 (10a, 10b, 10a′, 10b′) by e.g., YAG laser welding as one laser welding. In FIGS. 3 and 4, this welding portion is shown by a black circle P.

When adjacent metals are joined to each other by laser welding, power of the laser beam irradiated to a objected joint portion of these adjacent metals is conventionally controlled in a pulse shape as shown in e.g. 7A. Thus, the power of the laser beam suddenly becomes zero from a high level for momentarily welding the metals at a terminating time of the irradiation of the laser beam. Therefore, the metals melted and fused by the irradiation of the laser beam are suddenly cooled and solidified by the termination of the irradiation of the laser beam.

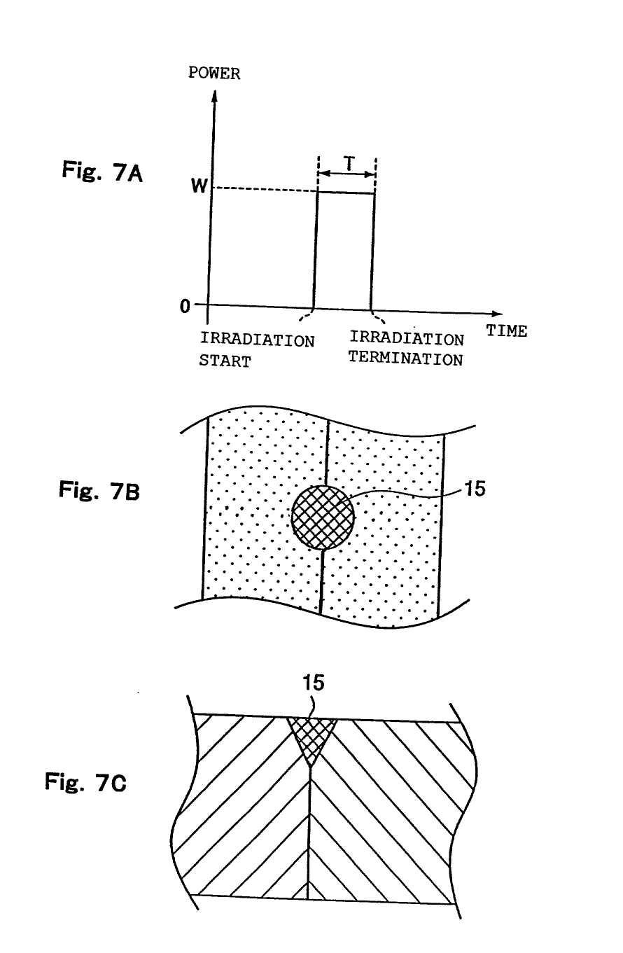

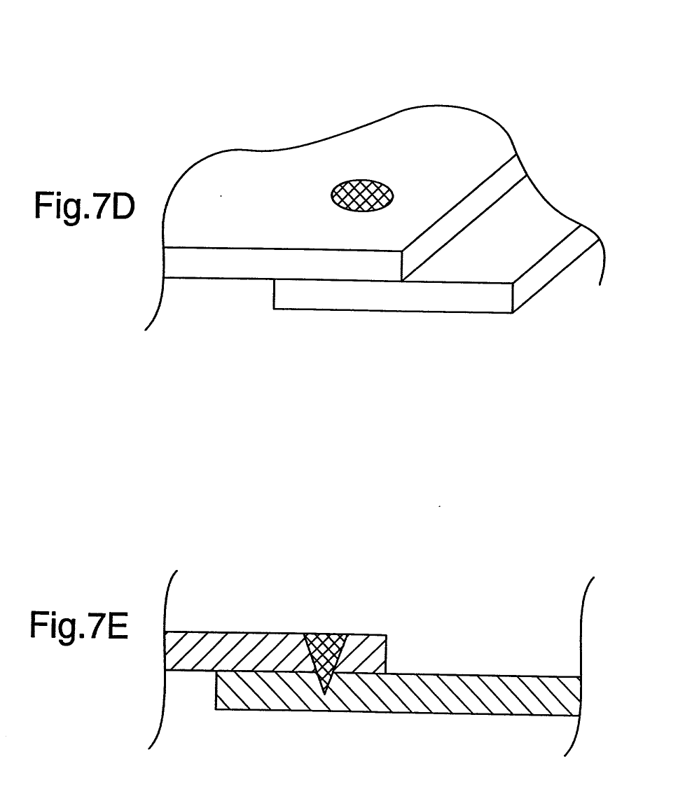

The shape of a laser welding trace is changed by various factors such as laser intensity, a focal length, an irradiating angle, a material and a material shape. For example, in one example of the shape of the laser welding trace in which the laser beam is controlled in the pulse shape, the laser welding trace is formed in an approximately circular shape as shown in FIG. 7B when the laser welding trace is seen from a laser irradiating side. Further, the laser welding trace is approximately formed in a V-shape in section as shown in FIG. 7C.

In one example in which the ferrule 11 is welded to the fixing portion 10 by the YAG laser welding, the laser beam having 25 W in power W as 50% of a laser output in a laser processor having a laser output function of 50 W in maximum power is irradiated to the objected joint portion of the ferrule 11 and the fixing portion 10 for only a very short irradiating time T such as about 2 ms so that the ferrule 11 and the fixing portion 10 are welded and joined to each other.

As mentioned above, since the power of the laser beam is conventionally controlled in the pulse shape, the molten metals are suddenly cooled from the outside of a molten portion to the inside of the molten portion by the termination of the irradiation of the laser beam. Therefore, when the molten metals are solidified, there is a case in which an air bubble is confined within the metals in this welding portion. Further, since the molten metals are suddenly cooled and solidified from the outside of the molten portion to the inside of the molten portion, the molten metals are greatly influenced by the difference in cooling solidification speed due to the difference in the melting point temperatures of metallic material components of the molten metals so that a crack is easily caused in a welding portion. The air bubble and the crack cause the deterioration of welding strength and are a great problem.

Similarly, the sudden cooling solidification of the molten metals from the outside of the molten portion to the inside of the molten portion is greatly influenced by the difference in cooling solidification speed due to the difference in the melting point temperatures of the metallic material components of the molten metals. Accordingly, large residual stress is easily caused within the metals in the welding portion. There is a fear that the following problem is caused by this residual stress. For example, in an inspecting process of the semiconductor laser module 1, there is a case in which an endurance tests of the semiconductor laser module 1 are made by leaving the semiconductor laser module 1 under an environment at high temperature (e.g., about 85° C.) and placing the semiconductor laser module 1 under the environment of a temperature cycle changing from room temperature to high temperature (e.g., about 85° C.).

In this case, when there is large residual stress within the metals in the welding portion, there is a case in which a large change in volume is caused in this welding portion by the high temperature environment and a large environmental temperature change. For example, the ferrule 11 is shifted in position when the large change in volume is caused in the welding portion of the ferrule 11 and the fixing portion 10. Therefore, there is a case in which an aligning work for aligning the position of an optical axis of the semiconductor laser element 2 and the position of an optical axis of the optical fiber 3 is made during a manufacturing process of the semiconductor laser module 1, but the optical axis of the semiconductor laser element 2 and the optical axis of the optical fiber 3 are shifted from each other by the position shift of the ferrule 11 in the inspecting process after the manufacture. Namely, there is a fear that the problem is caused by damaging the optical coupling of the semiconductor laser element 2 and the optical fiber 3.

The present invention in one aspect provides a laser welding method and a semiconductor laser module manufactured by using this method in which the generation of a crack and the inclusion of an air bubble in a welding portion can be reduced, and residual stress of the welding portion can be reduced and restrained.

Embodiments in this invention will next be explained on the basis of the drawings.

In this embodiment, one embodiment of a laser welding method in the present invention will be explained by using the semiconductor laser module 1 as shown in FIG. 3. The construction of the semiconductor laser module 1 shown in FIG. 3 has been already described. Therefore, an overlapping explanation of the semiconductor laser module 1 is omitted here.

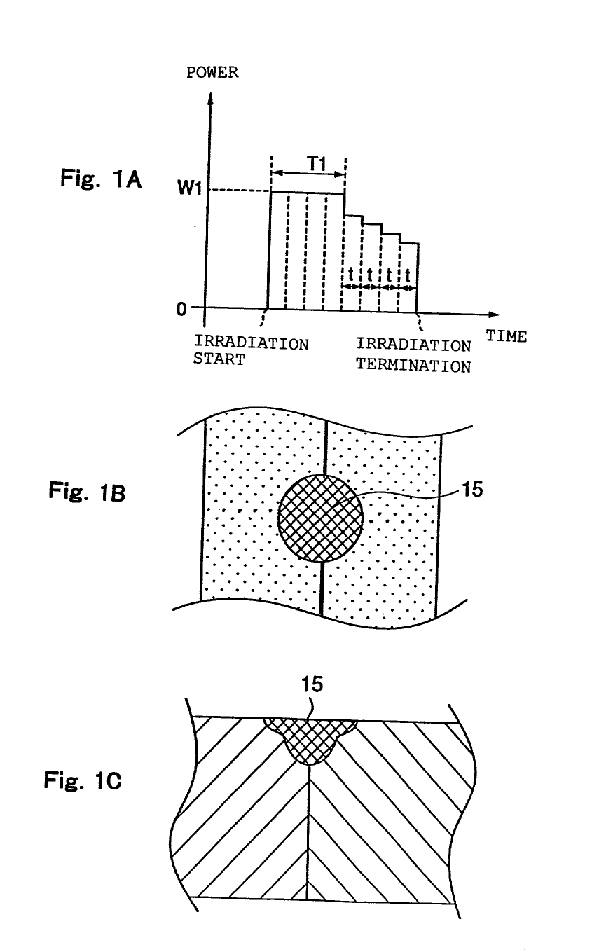

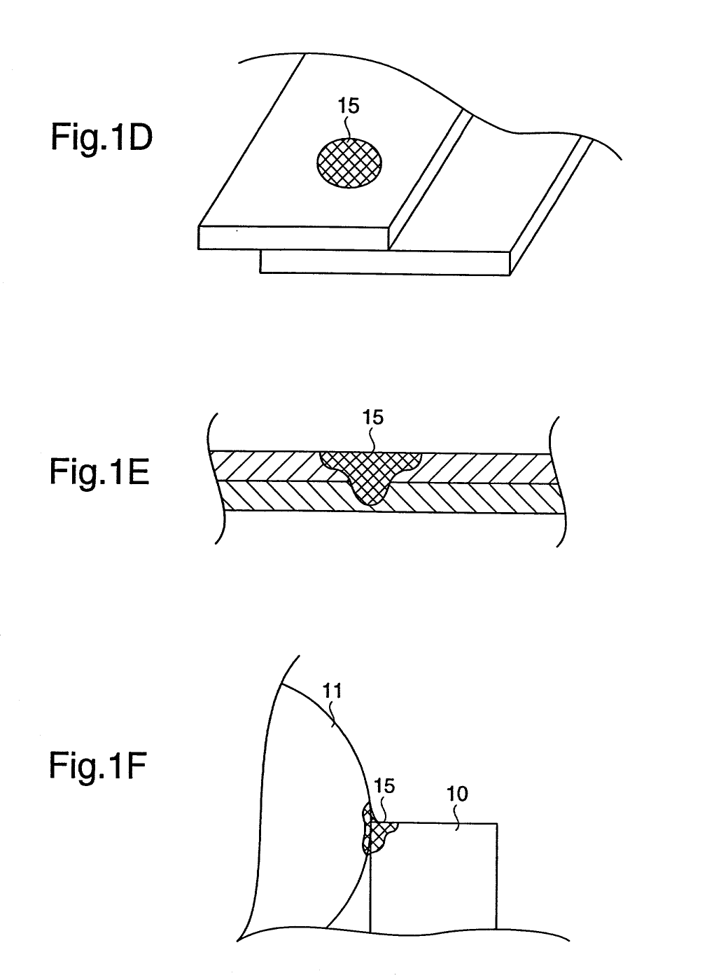

For example, when a objected welding portion such as a joining portion of the fixing portion 10 and the ferrule 11 is laser-welded in a manufacturing process of the semiconductor laser module 1, the power of a laser beam irradiated to this objected welding portion is controlled as shown in FIG. 1A. For example, YAG laser welding can be used as one of laser welding.

Namely, in this embodiment, when the laser beam begins to be irradiated to the objected welding portion, power W1 at this irradiation starting time is maintained during a predetermined time T1. This power W1 of the laser beam at the irradiation starting time is power able to melt metals in the objected welding portion by the irradiation of the laser beam. The maintaining time T1 of the power W1 is a time able to melt and fuse the metals in the welding object portion by the irradiation of the laser beam of the power W1. The power W1 and the time T1 are suitably set in consideration of various conditions such as metallic kinds of the welding object and a metallic shape of the welding object portion.

For example, in one example in which the fixing portion 10 and the ferrule 11 are welded by the YAG laser and a YAG laser welding machine of 50W is used, the power W1 at the irradiation starting time is set to 50% (i.e., 25W) of maximum power (50W), and the time T1 for maintaining this power W1 is set to 2 ms. In other words, in this example, the power W1 at the irradiation starting time is set to be approximately equal to the power W of a pulse in conventional power control of the laser beam (see FIG. 7A). The maintaining time T1 of the power W1 is set to be approximately equal to a time width T of the pulse in the conventional power control of the laser beam.

In this embodiment, after the time T1 has passed from the beginning of the irradiation of the laser beam, the power of the laser beam is reduced step by step. For example, in one example in which the fixing portion 10 and the ferrule 11 are welded by the YAG laser, the power is reduced step by step such as 45%, 40%, 35% and 30% of the maximum power W1 (e.g., 50W). In this example, the power maintaining time t for every one stage are similarity, and this time t is shorter than the maintaining time T1 of the power W1 at the irradiation starting time. For example, this time t is set to about 0.5 ms. In this case, when the power of the laser beam is controlled by a time slot with 0.5 ms as one unit, the power control of the laser beam and a change in power setting can be easily made. For example, the power of the laser beam can be controlled as shown in FIG. 1A by setting the power of the laser beam of first four time slots to W1 and gradually reducing the power of latter four time slots.

FIGS. 1B, 1C, 1D, 1E and 1F show examples of a laser welding trace 15 when the power of the laser beam is reduced step by step as shown in this embodiment. FIG. 1B typically shows a shape example of the laser welding trace 15 when the metals are laser-joined by irradiating the laser beam to a boundary portion between the adjacent metals as in a laser welding case of the ferrule 11 and the fixing portion 10. FIG. 1C shows a typical sectional view of the laser welding trace 15 of FIG. 1B. FIG. 1D typically shows a shape example of the laser welding trace 15 when the metals are laser-welded by irradiating the laser beam from an upper side of the overlapping metals as in a laser welding case of the substrate 15 of the part 17 for fixation and the base 6. FIG. 1E shows a typical sectional view of the laser welding trace 15 of FIG. 1D. FIG. 1F shows one example of the laser welding trace 15 of the ferrule 11 and the fixing portion 10.

As shown in these figures, in this embodiment, the laser welding trace 15 has an entirely round shape or a stepped round shape in comparison with the laser welding trace 15 as shown in each of FIGS. 7B, 7C, 7D and 7E mentioned above.

In this embodiment, the irradiation of the laser beam is terminated after the power of the laser beam is reduced step by step. Accordingly, energy of the laser beam given to the molten metals at the irradiation terminating time is reduced in comparison with the irradiation starting time.

In accordance with this embodiment, since the irradiation of the laser beam is terminated after the power of the laser beam is reduced step by step, it is possible to relax sudden cooling solidification of the molten metals due to the subsequent reduction in temperature after the melting of metallic materials caused by the laser beam. Thus, the generation of a crack in the welding portion and an air bubble within the metals in the welding portion can be greatly reduced so that strength deterioration of the welding portion can be restrained, which is caused by the crack and the air bubble.

Further, since the sudden cooling solidification of the molten metals can be relaxed in this way, residual stress within the metals in the welding portion can be greatly reduced. Therefore, it is possible to restrain various kinds of problems caused when the residual stress is large. For example, when the residual stress of the welding portion of the fixing portion 10 and the ferrule 11 is large, this residual stress caused in the welding portion by a change in environmental temperature, etc. begins to be released in accordance with this change in temperature. As a result, there is a very high possibility that the position of the ferrule 11 is slightly changed by this stress. Thus, there may be a problem of deteriorating an optical coupled state of the semiconductor laser element 2 and the optical fiber 3 due to a position shift of the ferrule 11. In contrast to this, in this embodiment, since the residual stress of the welding portion can be greatly reduced, it is possible to avoid the position shift of the ferrule 11 caused by the large residual stress of the welding portion. Thus, a preferable state of optical coupling can be maintained for the semiconductor laser element 2 and the optical fiber 3. Accordingly, the reliability of durability of the semiconductor laser module 1 can be improved.

Further, in this embodiment, the power of the laser beam is reduced after the set time T1 (i.e., a time sufficient to melt and fuse the metals by the irradiation of the laser beam) has passed after the irradiation of the laser beam is started. Therefore, it is possible to prevent a welding defect due to a reduction in the power of the laser beam.

This invention is not limited to the embodiments, but various embodiment modes can be adopted. For example, the power of the laser beam is reduced at four stages in the embodiments. However, the number of stages of the power reduction control of the laser beam is not limited to four, but the power of the laser beam may be also reduced by a suitable stage number.

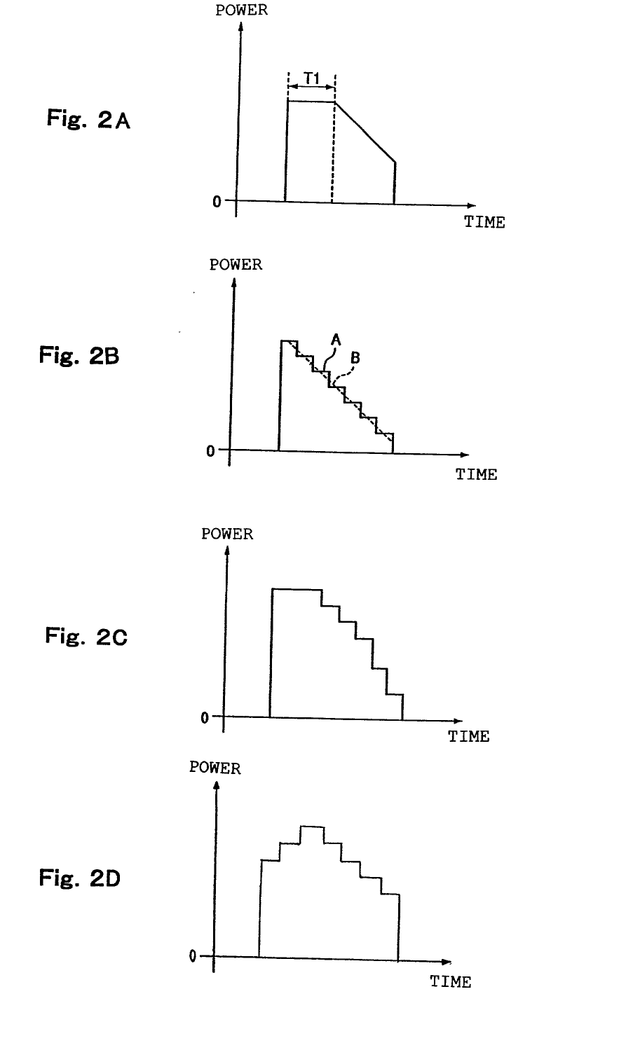

Further, in the embodiments, the power of the laser beam is reduced step by step when the power of the laser beam is reduced. However, for example, as shown in FIG. 2A, the power of the laser beam may be also reduced approximately continuously.

Further, in the embodiments, the power W1 at the beginning of irradiation is maintained until the set time T1 has passed after the beginning of irradiation. Thereafter, the power of the laser beam is reduced. However, for example, as shown in FIG. 2B, just after the irradiation of the laser beam is started, the power of the laser beam may begin to be reduced step by step as shown by a solid line A, or be continuously reduced as shown by a dotted line B.

Further, in the embodiments, the power of the laser beam is reduced in stages by the same power amount when the power of the laser beam is reduced. However, the reducing amount of the power for every one stage is not limited to an equal amount, but may be also set to be unequal as shown in FIG. 2C.

Further, in the embodiments, the laser beam of large power is irradiated from the laser irradiation starting time. However, for example, as shown in FIG. 2D, the power of the laser beam may be also reduced in stages or continuously from the irradiation starting time after the metals are melted by raising the power of the laser beam. In this case, the crack generation and the air bubble generation in the welding portion can be greatly reduced, and the residual stress can be greatly relaxed, and scattering of the metals at a welding time can be prevented. Furthermore, it is possible to improve the welding property of metallic materials comparatively bad in laser welding property.

Further, in the embodiments, the explanation has been made with the semiconductor laser module 1 shown in FIG. 3 as an example, but the laser welding method of the present invention can be also applied in the manufacture of a semiconductor laser module having a construction except for the semiconductor laser module 1 shown in FIG. 3. Further, the present invention can be also applied to the laser welding of parts constituting optical parts except for the semiconductor laser module. This invention is not used only in the manufacture of the optical parts, but can be also applied when the laser welding except for this manufacture is performed.

What is claimed is:

1. A laser welding method comprising:
irradiating a laser beam to a objected joining portion of metals adjacently arranged, and welding and joining the metals to each other;
wherein the irradiation of the laser beam is terminated after power of the laser beam irradiated to the objected joint portion is reduced step by step or continuously.

2. A laser welding method according to claim 1, wherein
a reduction in the power of the laser beam is controlled in a time slot unit.

3. A laser welding method according to claim 1, wherein
the objected joint portion is a joining portion of parts constituting optical parts.

4. A laser welding method according to claim 2 wherein
the objected joint portion is a joining portion of parts constituting optical parts.

5. A semiconductor laser module comprising:
a semiconductor laser module; and
an optical fiber;
wherein the optical fiber is optically coupled to the semiconductor laser element, and this optical fiber is inserted and fixed to a ferrule,
a pair of fixing portions is arranged in a nipping state in which a side face of this ferrule is nipped from both sides by the pair of fixing portions, and
the fixing portions and the ferrule are welded and fixed to each other by utilizing the laser welding method according to claim 1.

6. A semiconductor laser module comprising:
a semiconductor laser module; and
an optical fiber;
wherein the optical fiber is optically coupled to the semiconductor laser element, and this optical fiber is inserted and fixed to a ferrule,
a pair of fixing portions is arranged in a nipping state in which a side face of this ferrule is nipped from both sides by the pair of fixing portions, and
the fixing portions and the ferrule are welded and fixed to each other by utilizing the laser welding method according to claim 2.

7. A semiconductor laser module comprising:
a semiconductor laser module; and
an optical fiber;
wherein the optical fiber is optically coupled to the semiconductor laser element, and this optical fiber is inserted and fixed to a ferrule,
a pair of fixing portions is arranged in a nipping state in which a side face of this ferrule is nipped from both sides by the pair of fixing portions, and
the fixing portions and the ferrule are welded and fixed to each other by utilizing the laser welding method according to claim 3.

8. A semiconductor laser module comprising:
a semiconductor laser module; and
an optical fiber;
wherein the optical fiber is optically coupled to the semiconductor laser element, and this optical fiber is inserted and fixed to a ferrule,
a pair of fixing portions is arranged in a nipping state in which a side face of this ferrule is nipped from both sides by the pair of fixing portions, and
the fixing portions and the ferrule are welded and fixed to each other by utilizing the laser welding method according to claim 4.

9. A semiconductor laser module according to claim 5, wherein
the pair of fixing portions is of an integral type or a separating type.

10. A semiconductor laser module according to claim 6, wherein
the pair of fixing portions is of an integral type or a separating type.

11. A semiconductor laser module according to claim 7, wherein
the pair of fixing portions is of an integral type or a separating type.

12. A semiconductor laser module according to claim 8, wherein
the pair of fixing portions is of an integral type or a separating type.
